(19) United States
(12) Patent Application Publication
(10) Pub. No.: US 2023/0134408 A1
(43) Pub. Date: May 4, 2023

(54) METHOD FOR INDUCING CONDUCTIVITY AT AND NEAR OXIDE INTERFACES

(71) Applicant: Technion Research & Development Foundation Limited, Haifa (IL)

(72) Inventors: Lior KORNBLUM, Haifa (IL); Dana COHEN AZARZAR, Haifa (IL); Maria BASKIN, Haifa (IL); Yang LI, Haifa (IL)

(73) Assignee: Technion Research & Development Foundation Limited, Haifa (IL)

(21) Appl. No.: 17/917,948

(22) PCT Filed: Apr. 15, 2021
(86) PCT No.: PCT/IL2021/050431

§ 371 Date: Oct. 10, 2022

Related U.S. Application Data
(60) Provisional application No. 63/010,751, filed on Apr. 16, 2020.

(51) Int. Cl. C23C 16/56; C23C 16/455; H01L 21/02; C23C 16/40

(52) U.S. Cl. CPC C23C 16/56; C23C 16/45553; H01L 21/02274; H01L 21/0228; C23C 16/45536; C23C 16/405; C23C 16/402; C23C 16/403

(57) ABSTRACT

A process of preparing a conductive oxide interface is described herein, comprising contacting a surface of a first oxide with a plasma of a reducing gas to obtain a treated surface, and depositing a second oxide on the treated surface, thereby obtaining a conductive oxide interface between the first oxide and the second oxide. Further described herein are composites and articles of manufacture comprising same, the composites comprising a first oxide and second oxide, and an interface between the first oxide and second oxide which comprises a conductive oxide interface, wherein the conductive oxide interface comprises nitrogen atoms and/or the second oxide is in an amorphous form and the conductive oxide interface is characterized by a sheet resistance of no more than 10⁵ omega/square.

### RELATED APPLICATION/S

This application claims the benefit of priority of U.S. Provisional Patent Application No. 63/010,751 filed on Apr. 16, 2020, the contents of which are incorporated herein by reference in their entirety.

### FIELD AND BACKGROUND OF THE INVENTION

The present invention, in some embodiments thereof, relates to materials science, and more particularly, but not exclusively, to oxide interfaces which are useful, for example, in electronics.

Oxide electronics is an emerging field striving to harness the complex and rich physical phenomena encompassed in oxides towards practical electronic devices. This transition from fundamental science towards technology has shown considerable promise for devices such as transistors, chemical sensors, quantum computing, spintronics, and optoelectronics.

Some promising applications in oxide electronics are based on conductive oxide interfaces, which host what is often referred to as two-dimensional electron gases (2 DEGs) or quasi-two-dimensional electron gases (which terms are used herein interchangeably). This term refers to the presence of a high density of charge carriers (typically electrons) at or near the interface between two initially insulating oxides. The most common example is the epitaxial interface between SrTiO₃ (STO) and LaAlO₃ (LAO); and while many other combinations are possible, STO remains the most common substrate to host these phenomena.

The most common route for fabricating conductive oxide interfaces is by epitaxial growth, involving careful deposition of a single-crystalline layer (e.g. LAO) over a single-crystalline substrate such as STO [Ohtomo & Hwang, Nature 2004, 427:423-426]. Epitaxial growth of oxides is typically slow and costly, with the most common technique of pulsed-laser deposition (PLD) also suffering from limited scalability.

In 2011, Chen et al. [Nano Lett 2011, 11:3774-3778] reported that conductive oxide interfaces can be formed at LAO/STO interfaces using pulsed-laser deposition (PLD) without epitaxy.

Lee et al. [Nano Lett 2012, 12:4775-4783] reported that conductive oxide interfaces can be produced using the atomic layer deposition (ALD) technique, a process compatible with mass production, using various layers, including Al₂O₃ (AO) or LaAlO₃ (LAO) on STO. Carrier densities were 3·10¹² per cm² for AO/STO, and about 10¹³ per cm² or less for LAO/STO.

Moon et al. [APL Mater 2017, 5:42301] describe a capacitor comprising a conductive interface formed from atomic layer-deposited Al₂O₃ on SrTiO₃, in which the sheet resistance is about 2.25·10⁵ Ω/square.

Additional background art includes Hwang [Nature Materials 2012, 11:103]; Miron et al. [Appl Phys Lett 2020, 116:223503]; and Bogorin et al. [“LaAlO₃/SrTiO₃-Based Device Concepts” in Tsymbal, E. Y.; Dagotto, E.; Eom, C. B.; Ramesh, R. (eds.), Multifunctional Oxide Heterostructures. Oxford University Press, 24 Nov. 2010].

### SUMMARY OF THE INVENTION

According to an aspect of some embodiments of the invention, there is provided a process of preparing a conductive oxide interface, the process comprising contacting a surface of a first oxide with a plasma of a reducing gas to obtain a treated surface, and depositing a second oxide on the treated surface, thereby obtaining a conductive oxide interface between the first oxide and the second oxide.

According to an aspect of some embodiments of the invention, there is provided a composite comprising a first oxide and a second oxide, and an interface between the first oxide and the second oxide which comprises a conductive oxide interface obtainable according to the process described herein, according to any of the respective embodiments.

According to an aspect of some embodiments of the invention, there is provided a composite comprising a first oxide and a second oxide, and an interface between the first oxide and the second oxide which comprises a conductive oxide interface, the conductive oxide interface comprising nitrogen atoms.

According to an aspect of some embodiments of the invention, there is provided a composite comprising a first oxide and a second oxide, the second oxide being in an amorphous form, and an interface between the first oxide and the second oxide which comprises a conductive oxide interface characterized by a sheet resistance of no more than 10⁵ Ω/square.

According to an aspect of some embodiments of the invention, there is provided an article of manufacture comprising a device described herein, according to any of the respective embodiments.

According to some of any of the embodiments described herein relating to a process, the depositing comprises atomic layer deposition.

According to some of any of the embodiments described herein relating to a process, the reducing gas comprises at least one gas selected from the group consisting of ammonia, hydrazine, hydrogen and nitrogen.

According to some of any of the embodiments described herein relating to a process, the reducing gas comprises nitrogen atoms.

According to some of any of the embodiments described herein relating to a process, the reducing gas comprises ammonia.

According to some of any of the embodiments described herein relating to a process, the contacting is effected for at least 3 seconds.

According to some of any of the embodiments described herein relating to a process, the contacting is effected for a time period in a range of from 10 seconds to 30 minutes.

According to some of any of the embodiments described herein relating to a process, the process comprises controlling a conductivity and/or carrier density of the interface by controlling a time of exposure of the surface of a first oxide to the plasma.

According to some of any of the embodiments described herein relating to a process comprising controlling a time of exposure of the surface to the plasma, controlling a time of exposure of the surface to the plasma is capable of altering a sheet resistance of an obtained interface by at least 250-fold, optionally at least 1,000-fold.

According to some of any of the embodiments described herein relating to a process, the process further comprised subjecting the first oxide to a thermal treatment at a temperature of at least 200° C., prior to the contacting with the plasma of a reducing gas.

According to some of any of the embodiments described herein, a sheet resistance of the conductive oxide interface is within a range of from 10² to 10⁷ Ω/square.

According to some of any of the embodiments described herein, a sheet resistance of the conductive oxide interface is no more than 10⁵ Ω/square.

According to some of any of the embodiments described herein, the sheet resistance is no more than 3·10³ Ω/square.

According to some of any of the embodiments described herein, a carrier density of the conductive oxide interface is within a range of from 10¹¹ to 10¹⁶ per cm².

According to some of any of the embodiments described herein, a carrier density of the conductive oxide interface is at least 10¹⁴ per cm².

According to some of any of the embodiments described herein, the first oxide is selected from the group consisting of SrTiO₃, KTaO₃, and TiO₂.

According to some of any of the embodiments described herein, the surface is a (001)-oriented surface, a (011)-oriented surface, and/or a (111)-oriented surface of the first oxide.

According to some of any of the embodiments described herein, the second oxide is in a non-epitaxial form.

According to some of any of the embodiments described herein, the second oxide is in an amorphous form.

According to some of any of the embodiments described herein, the second oxide is selected from the group consisting of Al₂O₃, SiO₂, Si₃N₄, TiO₂, Ta₂O₅, LaAlO₃, YAlO₃ and Hf₁₋ₓZrₓO_{y}, wherein x is in a range of from 0 to 1 and y is in a range of from about 1.5 to about 2.

According to some of any of the embodiments described herein, the second oxide is Al₂O₃.

According to some of any of the embodiments described herein, the second oxide is amorphous Al₂O₃.

According to some of any of the embodiments described herein, the conductive oxide interface comprises nitrogen atoms.

According to some of any of the embodiments described herein, a concentration of nitrogen atoms in the conductive oxide interface is greater than a concentration of nitrogen atoms in the bulk of the first oxide and/or the second oxide.

According to some of any of the embodiments described herein, a concentration of oxygen atoms in the conductive oxide interface is less than a concentration of oxygen atoms in the bulk of the first oxide and/or the second oxide.

According to some of any of the embodiments described herein, upon subjecting the composite to a first threshold voltage, the composite transitions from a state characterized by a low resistance to a state characterized by a high resistance, wherein the high resistance is at least 10-fold the low resistance.

According to some of any of the embodiments described herein relating to a composite with a state characterized by high resistance, upon subjecting the composite in the state characterized by high resistance to a second threshold voltage, the composite transitions to the state characterized by a low resistance.

According to some of any of the embodiments described herein relating to a composite, the composite is in a form of a device or a component of a device.

According to some of any of the embodiments described herein relating to a device, the device further comprises an electric conductor in functional contact with at least one of the first oxide and the second oxide.

According to some of any of the embodiments described herein relating to a device, the device is selected from the group consisting of a memory cell, a transistor, a chemical sensor, an optical sensor, an electromagnetic radiation emitter, and a spin-logic device.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIGS. 1A and 1B present graphs showing experimentally determined sheet resistance (R_{S}) (FIG. 1A) and sheet electron density (n_{S}) calculated based on sheet resistance (FIG. 1B) of an (amorphous) Al₂O₃/(crystalline) SrTiO₃ interface, as a function of time of exposure of the SrTiO₃ surface to ammonia plasma prior to Al₂O₃ deposition.

FIG. 2 presents a cross-section high resolution scanning transmission electron microscopy image of an Al₂O₃/SrTiO₃ interface prepared according to some embodiments of the invention.

FIG. 3 presents a graph showing sheet resistance (R_{S}) of an Al₂O₃/TiO₂ interface, as a function of time of exposure of the TiO₂ surface to NH₃ plasma prior to Al₂O₃ deposition.

FIG. 4 presents a graph showing sheet resistance (R_{S}) of Al₂O₃/TiO₂ interfaces, as a function of time of exposure of the surface of the TiO₂ layer (14 or 20 nm thick) to NH₃ plasma prior to deposition of a 10 nm layer of Al₂O₃.

FIG. 5 presents a graph showing sheet resistance (R_{S}) of Al₂O₃/TiO₂ interfaces, as a function of the temperature of thermal treatment (annealing) of the TiO₂ layer (14 nm thick) prior to exposure of the TiO₂ surface to NH₃ plasma (for 15 minutes) and deposition of a 10 nm layer of Al₂O₃.

FIG. 6 presents a schematic depiction of an exemplary device comprising an Al₂O₃/TiO₂ interface according to some embodiments of the invention.

FIG. 7 presents a graph showing current as a function of voltage, upon subjecting an exemplary device comprising an Al₂O₃/TiO₂ interface (characterized by a sheet resistance of 3.78·10³ Ω/square) according to some embodiments of the invention to multiple current-voltage sweep cycles.

FIG. 8 presents a graph showing the resistances of distinct high resistance and low resistance states of an exemplary device comprising an Al₂O₃/TiO₂ interface (characterized by a sheet resistance of 3.78·10³ Ω/square according to some embodiments of the invention during multiple current-voltage sweep cycles.

### DESCRIPTION OF SPECIFIC EMBODIMENTS OF THE INVENTION

The present invention, in some embodiments thereof, relates to materials science, and more particularly, but not exclusively, to oxide interfaces which are useful, for example, in electronics.

Before explaining at least one embodiment of the invention in detail, it is to be understood that the invention is not necessarily limited in its application to the details of construction and the arrangement of the components and/or methods set forth in the following description. The invention is capable of other embodiments or of being practiced or carried out in various ways.

Although atomic layer deposition (ALD) represents a relatively low-cost, high-throughput and scalable technique, which is compatible with the microelectronics industry, ALD-formed conductive oxide interfaces (e.g., as described by Lee et al. [Nano Lett 2012, 12:4775-4783] and Moon et al. [APL Mater 2016, 5:42301]) have heretofore exhibited very low carrier density and hence very low conductivity, thus limiting their practical applications.

The present inventors have designed and practiced a method of preparing conductive oxide interfaces in which the carrier density and conductivity are both relatively high and controllable, the method being compatible with relatively low-cost, high-throughput and scalable techniques such as ALD. Such conductive oxide interfaces may be used, for example, for effecting memory storage (e.g., random access memory) and/or logic operations (e.g., in a computer or related device).

While reducing the present invention to practice, the inventors have shown that the sheet resistance of a conductive interface between two oxides can be sharply reduced, in a readily controllable manner, by treating a first oxide surface with ammonia plasma prior to deposition of a second oxide to form the conductive interface. The inventors have further shown that the resistance of exemplary conductive oxide interfaces can be controlled by exposure to suitable voltages, as would be suitable, for example, for a random access memory device.

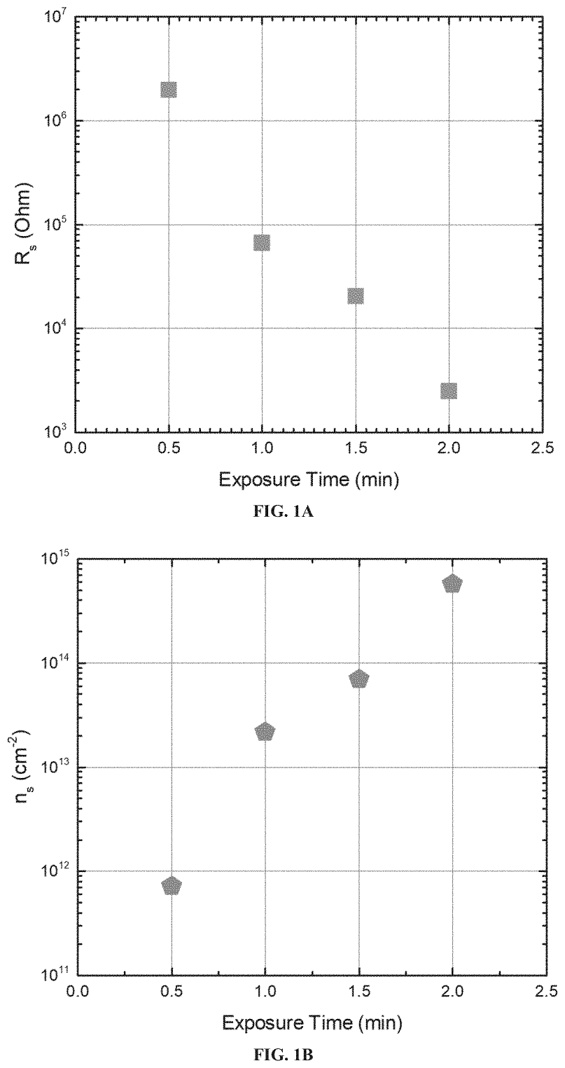

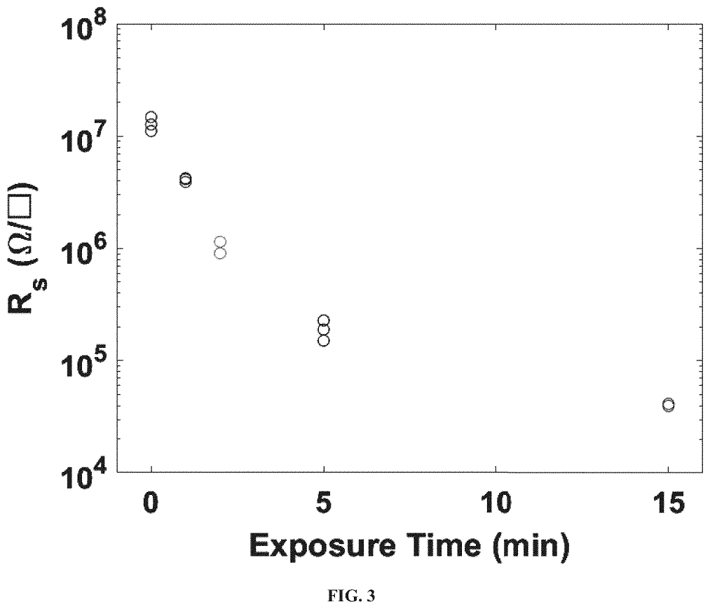

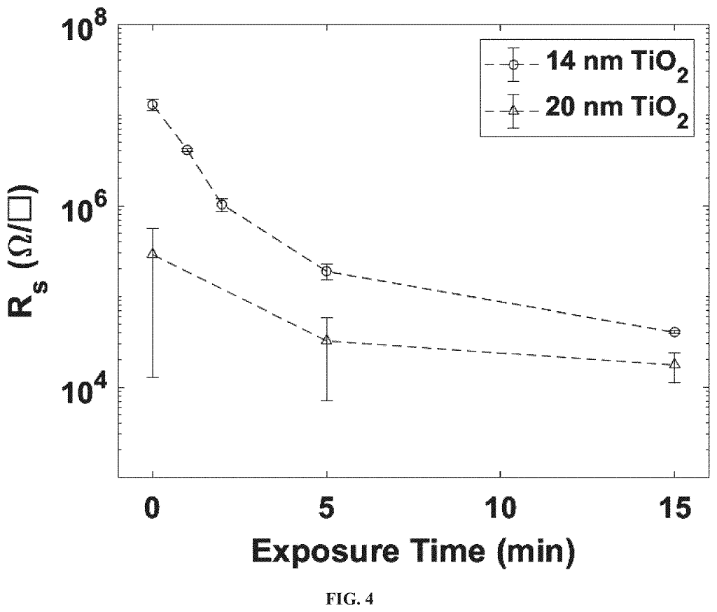

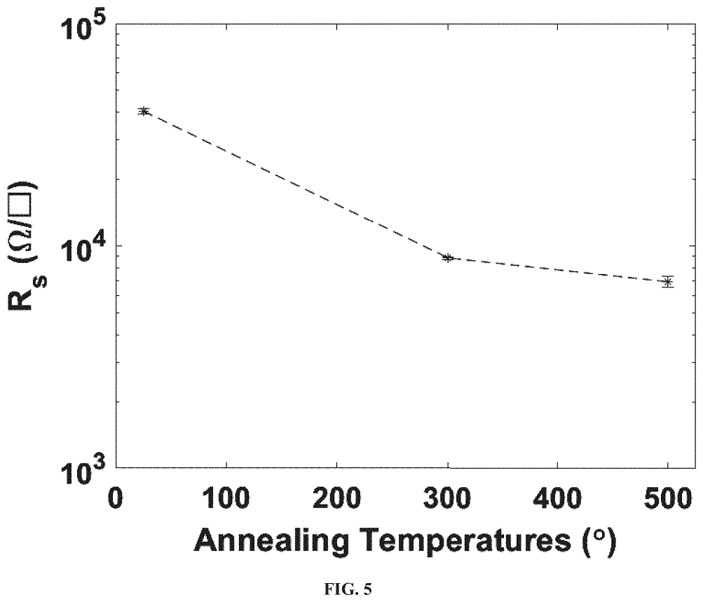

Referring now to the drawings, FIGS. 1A and 1B show that treatment of exemplary SrTiO₃ surfaces with ammonia plasma reduced the sheet resistance and increased the sheet electron density of obtained Al₂O₃/SrTiO₃ interfaces, in a manner dependent on the time of exposure to plasma. FIG. 3 shows similar results when TiO₂ is used instead of SrTiO₃. FIG. 4 shows that the sheet resistance of exemplary Al₂O₃/TiO₂ interfaces may be controlled by the exposure time. FIG. 5 shows that the sheet resistance of exemplary Al₂O₃/TiO₂ interfaces comprising a thin TiO₂ layer is reduced by thermal treatment of the TiO₂ layer.

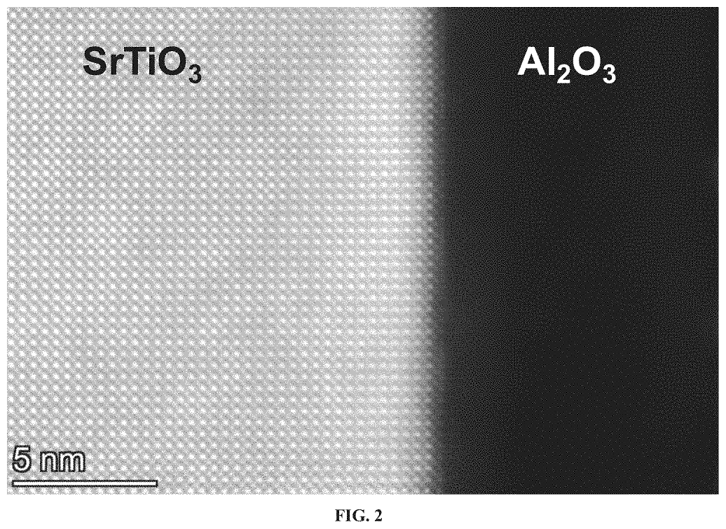

FIG. 2 shows an exemplary Al₂O₃/SrTiO₃ interface, as observed by high resolution scanning transmission electron microscopy.

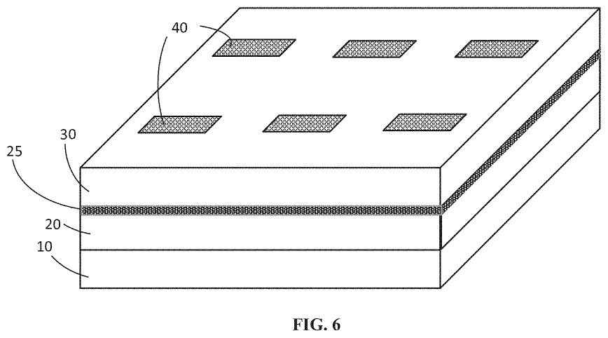

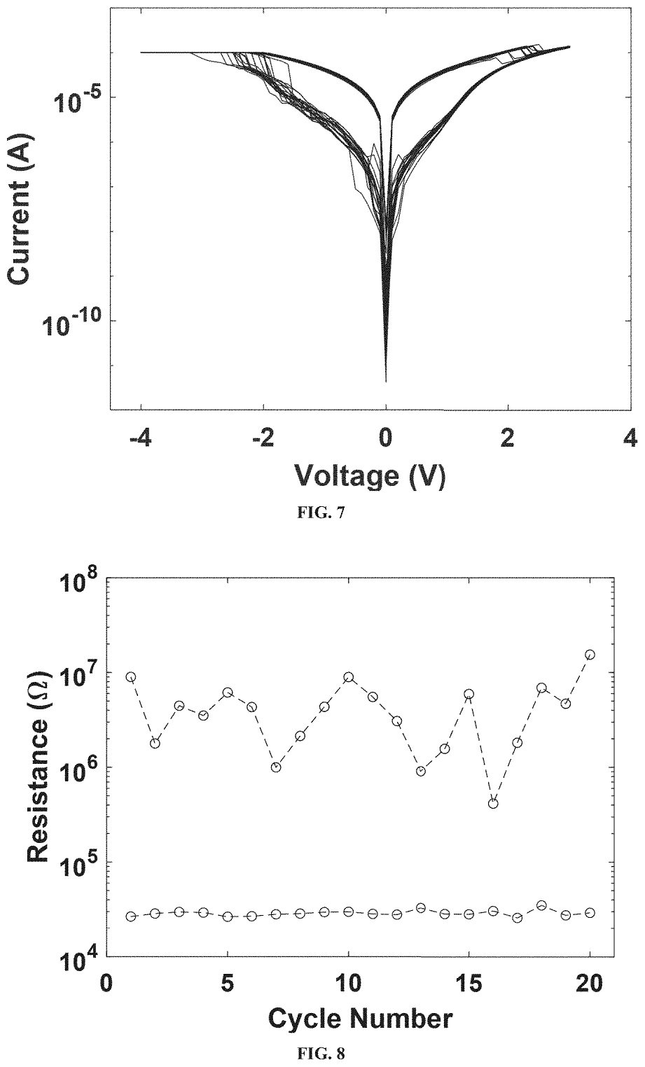

FIG. 6 shows an exemplary device comprising a conductive oxide interface. FIGS. 7 and 8 show that such a device exhibits distinct high resistance and low resistance states, which may be determined by the voltage to which the device is exposed. This property may be utilized, for example, for writing and reading in a computer memory device.

Process:

According to an aspect of some embodiments of the invention, there is provided a process of preparing a conductive oxide interface, the process comprising contacting a surface of a first oxide with a plasma of a reducing gas to obtain a treated surface, and depositing a second oxide on the treated surface, thereby obtaining a conductive oxide interface between the first oxide and the second oxide.

Herein, the term “interface” encompasses atoms in proximity to a two-dimensional plane (flat or curved) representing a border between two substances, for example, atoms within 5 nm of the border (e.g., forming a 10 nm-thick interface), atoms within 2.5 nm of the border (e.g., forming a 5 nm-thick interface), atoms within 1 nm of the border (e.g., forming a 2 nm-thick interface), and/or atoms within 0.5 nm of the border (e.g., forming a 1 nm-thick interface).

Herein, the term “conductive oxide interface” refers to an interface (as defined herein) between two oxides (as defined herein) which is substantially more electrically conductive than the bulk oxides, such that electric conductivity is limited to the vicinity of the plane interface, as opposed to a direction perpendicular to the interface (which direction is optionally characterized by a resistivity described herein). Such conductivity may optionally form a (quasi-) two-dimensional electron gas (as this term is used in the art).

As exemplified herein, plasma treatment according to embodiments of the invention is associated with a reduction in sheet resistance in the conductive oxide interface, that is, an increase in conductivity of the conductive oxide interface. Without being bound by any particular theory, it is believed that such an increase in conductivity allows for enhanced performance of the conductive oxide interface in a variety of applications.

Herein, the term “reducing gas” refers to a gas capable of reacting with oxygen atoms in a solid (e.g., a first oxide described herein) so as to form a gaseous substance comprising at least a portion of said oxygen atoms (e.g., thereby abstracting oxygen atoms from the solid).

According to some of any of the respective embodiments, depositing comprises atomic layer deposition.

It is expected that during the life of a patent maturing from this application many relevant deposition techniques will be developed and the scope of the terms “depositing” and “atomic layer deposition” are intended to include such new technologies a priori.

According to some of any of the respective embodiments, the reducing gas comprises at least one of ammonia, hydrazine, hydrogen (H₂) and/or nitrogen (N₂). Ammonia is an exemplary reducing gas.

According to some of any of the respective embodiments, the reducing gas comprises nitrogen atoms (for example, ammonia, hydrazine and/or nitrogen (N₂), optionally in combination with each other and/or with an additional gas, which may or may not comprise nitrogen atoms). In some such embodiments, the obtained interface is enriched in nitrogen atoms relative to the bulk of the first oxide and/or the second oxide (e.g., according to any of the respective embodiments described herein).

According to some of any of the respective embodiments, contacting a surface of a first oxide with a plasma of reducing gas is effected for at least 3 seconds, optionally at least 5 seconds, optionally at least 10 seconds, optionally at least 20 seconds, optionally at least 30 seconds, and optionally at least 1 minute.

According to some of any of the respective embodiments, contacting the surface with the plasma is effected for a time period of up to 30 minutes, for example, in a range of from 10 seconds to 30 minutes, or from 1 minute to 30 minutes; or for a time period of up to 10 minutes, for example, in a range of from 10 seconds to 10 minutes, or from 1 minute to 10 minutes.

According to some of any of the respective embodiments, the process comprises controlling a conductivity and/or carrier density of the interface by controlling a time of exposure of the surface of a first oxide to the plasma. In some embodiments, controlling a time of exposure of the surface to the plasma is capable of altering a sheet resistance of an obtained interface by at least 250-fold (and optionally at least 1,000-fold or at least 3,000-fold or at least 10,000-fold); that is two samples with sheet resistances differing by a factor of at least 1,000 can be obtained by the process, under substantially the same conditions (e.g., materials, pressure, reducing gas, plasma formation technique, and second oxide deposition procedures) except for time of exposure.

Alternatively or additionally, the process optionally comprises controlling a spatial pattern of the conductive oxide surface, for example, by contacting the plasma with only a portion of the first oxide surface (e.g., using a mask according to any suitable technique known in the art).

According to some of any of the respective embodiments, the process further comprises subjecting the first oxide and/or the second oxide to a thermal treatment, for example, at a temperature of at least 200° C., at least 300° C., at least 400° C., or at least 500° C. Such a thermal treatment may optionally be effected prior to deposition of the second oxide (e.g., for effecting thermal treatment of the first oxide), prior to, concomitant with and/or subsequent to plasma treatment; and/or subsequent to deposition of the second oxide (e.g., for effecting thermal treatment of the first oxide and/or the second oxide). In exemplary embodiments, thermal treatment of a first oxide (e.g., TiO₂) is effected prior to plasma treatment.

A thermal treatment according to any of the respective embodiments described herein may optionally be effected for at least 10 minutes (e.g., from 10 to 200 minutes, or from 10 to 60 minutes), optionally at least 20 minutes (e.g., from 20 to 200 minutes, or from 20 to 80 minutes), optionally at least 40 minutes (e.g., from 40 to 200 minutes, or from 40 to 100 minutes), optionally at least 60 minutes (e.g., from 60 to 200 minutes, or from 60 to 120 minutes), and optionally at least 100 minutes (e.g., from 100 to 200 minutes). The duration of thermal treatment may optionally be inversely correlated to the temperature, e.g., wherein a treatment for at least 100 minutes is suitable for a relatively low temperature (e.g., from about 200° C. to about 300° C.), whereas a treatment for less than 100 minutes is suitable for a relatively high temperature (e.g., at least about 400° C.).

As exemplified in the Examples herein, thermal treatment of a first oxide (e.g., TiO₂) can significantly reduce the sheet resistance of an obtained conductive oxide interface, e.g., in addition to a reduction associated with a plasma treatment described herein.

Without being bound by any particular theory, it is believed that thermal treatment of a first oxide reduces sheet resistance by enhancing crystallinity of the first oxide. It is further believed that thermal treatment is particularly useful in such a respect when the first oxide is initially characterized by little or no crystallinity, for example, when the first oxide is in a form of a very thin layer (e.g., less than 30 nm thick).

Oxides:

A first oxide and/or second oxide according to any of the respective embodiments described herein (e.g., an interface in a composite described herein and/or obtained according to a process described herein) may optionally be in accordance with any one or more of the embodiments described in this section (except when specifically indicated otherwise).

Herein, the term “oxide” encompasses any substance comprising a stoichiometric amount of oxygen atoms and at least one other type of atom, preferably including at least one type of metal atom. The stoichiometric amount of oxygen atoms is in accordance with the valence of the other atom.

The first oxide and second oxide are preferably solid substances which are electrically non-conductive, for example, having a resistivity (e.g., at 20° C.) of at least 10 Ω·meter, or at least 10³ Ω·meter, or at least 10⁵ Ω·meter, or at least 10⁷ Ω·meter, or at least 10⁹ Ω·meter, or at least 10¹¹ Ω·meter, or at least 10¹³ Ω·meter, or at least 10¹⁵ Ω·meter, or even at least 10¹⁷ Ω·meter.

According to some of any of the respective embodiments, the first oxide is SrTiO₃, KTaO₃, and/or TiO₂. SrTiO₃ and TiO₂ are exemplary first oxides. As exemplified herein, SrTiO₃ responds particularly well to plasma treatment according to embodiments described herein.

According to some of any of the respective embodiments, the surface is a (001)-oriented surface, a (011)-oriented surface, and/or a (111)-oriented surface of the first oxide; for example, a (001)-oriented surface of SrTiO₃.

The first oxide may optionally be in a form of a thin layer, for example, a layer of no more than 1 mm in thickness, a layer of no more than 100 μm in thickness, a layer of no more than 10 μm in thickness, a layer of no more than 1 μm in thickness, and/or a layer of no more than 100 nm in thickness.

A layer of first oxide (e.g., TiO₂) is optionally at least 10 nm in thickness (e.g., from 10 nm to 1 mm, or from 10 nm to 100 μm, or from 10 nm to 10 μm, or from 10 nm to 1 μm, or from 10 nm to 100 nm in thickness), optionally at least 20 nm in thickness (e.g., from 20 nm to 1 mm, or from 20 nm to 100 μm, or from 20 nm to 10 μm, or from 20 nm to 1 μm, or from 20 nm to 100 nm in thickness), and optionally at least 30 nm in thickness (e.g., from 30 nm to 1 mm, or from 30 nm to 100 μm, or from 30 nm to 10 μm, or from 30 nm to 1 μm, or from 30 nm to 100 nm in thickness).

A thin layer of first oxide (according to any of the respective embodiments described herein) may optionally be supported by an underlying substrate, for example, a substrate comprising a polymer, glass, SiO₂ and/or silicon. Exemplary substrates include glass substrates and SiO₂-coated silicon substrates.

A thin layer of first oxide (according to any of the respective embodiments described herein) may optionally be prepared by atomic layer deposition and/or by sputtering, for example, onto a substrate according to any of the respective embodiments. As exemplified in the Examples herein, a thin TiO₂ layer may optionally be prepared by atomic layer deposition using a precursor comprising titanium attached to four alkoxy and/or alkylamino groups, for example, TTIP (titanium tetraisopropoxide) or TDMAT (tetrakis(dimethylamino)titanium).

The first oxide is optionally at least partially crystalline. As discussed elsewhere herein, a crystallinity of a first oxide (e.g., a thin layer of a first oxide) may optionally be enhanced by thermal treatment (e.g., according to any of the respective embodiments described herein).

According to some of any of the respective embodiments, the second oxide is Al₂O₃, SiO₂, Si₃N₄, TiO₂, Ta₂O₅, LaAlO₃, YAlO₃ and/or Hf₁₋ₓZrₓO_{y} (wherein x is in a range of from 0 to 1; and y is in a range of from about 1.5 to about 2, optionally about 2). HfO₂ and ZrO₂ are non-limiting examples of Hf₁₋ₓZrₓO_{y}. Al₂O₃ (e.g., amorphous Al₂O₃) is an exemplary second oxide.

According to some of any of the respective embodiments, the second oxide (at the conductive oxide interface) is in a non-epitaxial form.

Herein, the term “non-epitaxial” refers to a substance (e.g., second oxide) which does not feature crystal growth in a single orientation defined with respect to a substrate (e.g., the first oxide surface). The lack of orientation may be due to crystal growth being in multiple orientations (e.g. in a polycrystalline substance) and/or due to an absence of crystals (e.g., in an amorphous substance).

According to some of any of the respective embodiments, the second oxide (at the conductive oxide interface) is in an amorphous form.

The second oxide may optionally be in a form of a thin layer, for example, a layer of no more than 1 mm in thickness, a layer of no more than 100 μm in thickness, a layer of no more than 10 μm in thickness, a layer of no more than 1 μm in thickness, a layer of no more than 100 nm in thickness, and/or a layer of no more than 10 nm in thickness.

A layer of second oxide (e.g., Al₂O₃) is optionally at least 2 nm in thickness (e.g., from 2 nm to 1 mm, or from 2 nm to 100 μm, or from 2 nm to 10 μm, or from 2 nm to 1 μm, or from 2 nm to 100 nm, or from 2 nm to 10 nm in thickness), optionally at least 4 nm in thickness (e.g., from 4 nm to 1 mm, or from 4 nm to 100 μm, or from 4 nm to 10 μm, or from 4 nm to 1 μm, or from 4 nm to 100 nm, or from 4 nm to 10 nm in thickness), and optionally at least 10 nm in thickness (e.g., from 10 nm to 1 mm, or from 10 nm to 100 μm, or from 10 nm to 10 μm, or from 10 nm to 1 μm, or from 10 nm to 100 nm, or from 10 nm to 30 nm in thickness).

Conductive oxide interface properties:

A conductive oxide interface according to any of the respective embodiments described herein (e.g., an interface in a composite described herein and/or obtained according to a process described herein) may optionally exhibit properties according to any one or more of the embodiments described in this section (except when specifically indicated otherwise).

According to some of any of the respective embodiments, a sheet resistance of the conductive oxide interface is no more than 10⁷ Ω/square, for example, within a range of from 10² to 10⁷ Ω/square, or from 10³ to 10⁷ Ω/square, or from 10⁴ to 10⁷ Ω/square. In some such embodiments, the sheet resistance of the conductive oxide interface is no more than 10⁶ Ω/square, for example, within a range of from 10² to 10⁶ Ω/square, or from 10³ to 10⁶ Ω/square, or from 10⁴ to 10⁶ Ω/square. In some such embodiments, the sheet resistance of the conductive oxide interface is no more than 10⁵ Ω/square, for example, within a range of from 10² to 10⁵ Ω/square, or from 10³ to 10⁵ Ω/square, or from 10⁴ to 10⁵ Ω/square. In some such embodiments, the sheet resistance of the conductive oxide interface is no more than 3·10⁴ Ω/square, for example, within a range of from 10² to 3·10⁴ Ω/square, or from 10³ to 3·10⁴ Ω/square. In some such embodiments, the sheet resistance of the conductive oxide interface is no more than 10⁴ Ω/square, for example, within a range of from 10² to 10⁴ Ω/square, or from 10³ to 10⁴ Ω/square. In some such embodiments, the sheet resistance of the conductive oxide interface is no more than 3·10³ Ω/square, for example, within a range of from 10² to 3·10³ Ω/square. In some such embodiments, the sheet resistance of the conductive oxide interface is no more than 10³ Ω/square, for example, within a range of from 10² to 10³ Ω/square.

Sheet resistance may be determined according to any suitable technique known in the art, optionally using van der Pauw geometry (as exemplified herein), e.g., at about 20° C.

According to some of any of the respective embodiments, a carrier density of the conductive oxide interface is at least 10¹¹ per cm², for example, within a range of from 10¹¹ to 10¹⁷ per cm², or from 10¹¹ to 10¹⁶ per cm², or from 10¹¹ to 10¹⁵ per cm², or from 10¹¹ to 10¹⁴ per cm², or from 10¹¹ to 10¹³ per cm², or from 10¹¹ to 10¹² per cm². In some such embodiments, the carrier density is at least at least 10¹² per cm², for example, within a range of from 10¹² to 10¹⁷ per cm², or from 10¹² to 10¹⁶ per cm², or from 10¹² to 10¹⁵ per cm², or from 10¹² to 10¹⁴ per cm², or from 10¹² to 10¹³ per cm². In some embodiments, the carrier density is at least 10¹³ per cm², for example, within a range of from 10¹³ to 10¹⁷ per cm², or from 10¹³ to 10¹⁶ per cm², or from 10¹³ to 10¹⁵ per cm², or from 10¹³ to 10¹⁴ per cm². In some embodiments, the carrier density is at least 10¹⁴ per cm², for example, within a range of from 10¹⁴ to 10¹⁷ per cm², or from 10¹⁴ to 10¹⁶ per cm², or from 10¹⁴ to 10¹⁵ per cm². In some embodiments, the carrier density is at least 3·10¹⁴ per cm², for example, within a range of from 3·10¹⁴ to 10¹⁷ per cm², or from 3·10¹⁴ to 10¹⁶ per cm², or from 3·10¹⁴ to 10¹⁵ per cm². In some embodiments, the carrier density is at least 10¹⁵ per cm², for example, within a range of from 10¹⁵ to 10¹⁷ per cm², or from 10¹⁵ to 10¹⁶ per cm². In some embodiments, the carrier density is at least 3·10¹⁵ per cm², for example, within a range of from 3·10¹⁵ to 10¹⁷ per cm², or from 3·10¹⁵ to 10¹⁶ per cm². In some embodiments, the carrier density is at least 10¹⁶ per cm², for example, within a range of from 10¹⁶ to 10¹⁷ per cm².

Herein, the term “carrier density” refers to the number of charge carriers per space, and in the context of a conductive interface refer to charge carriers per area of interface (e.g., as opposed to a conductive bulk substance, in which the density would refer to charge carriers per volume), optionally at about 20° C.

Carrier density may be determined by any suitable technique known in the art, for example, by measuring a Hall effect. In a Hall effect, a voltage difference transverse to a current is produced by an applied magnetic field, and the ratio of the induced electric field to the applied magnetic field is proportional to the carrier density.

Composite:

According to an aspect of some embodiments of the invention, there is provided a composite comprising a first oxide and a second oxide, and an interface between the first oxide and the second oxide which comprises a conductive oxide interface.

Herein, the term “composite” refers to a material formed from two or more constituent materials, wherein at least a portion of the constituent materials remain separate and distinct within the structure of the composite.

According to some of any of the embodiments relating to a composite, the conductive oxide interface is obtainable according to a process according to any of the respective embodiments described herein.

According to some of any of the embodiments relating to a composite, the conductive oxide interface comprises nitrogen atoms.

In some embodiments, a concentration of nitrogen atoms in the conductive oxide interface is greater than a concentration of nitrogen atoms in the bulk of the first oxide and/or the second oxide. In some such embodiments, a concentration of nitrogen atoms in the conductive oxide interface is at least twice, at least 3-fold of, at least 5-fold of, at least 10-fold of, at least 100-fold of, at least 1,000-fold of, and/or at least 10,000-fold of a concentration of nitrogen atoms in the bulk of the first oxide and/or the second oxide. In some such embodiments, a concentration of nitrogen atoms in the conductive oxide interface is at least twice, at least 3-fold of, at least 5-fold of, at least 10-fold of, at least 100-fold of, at least 1,000-fold of, and/or at least 10,000-fold of a concentration of nitrogen atoms in the bulk of the first oxide.

According to some of any of the embodiments relating to a composite, a concentration of oxygen atoms in the conductive oxide interface is less than a concentration of oxygen atoms in the bulk of the first oxide and/or the second oxide. In some such embodiments, the concentration of oxygen atoms in the conductive oxide interface is no more than 99% or no more than 98% or no more than 95% or no more than 90% or no more than 80% or no more than 50% or no more than 20% of concentration of oxygen atoms in the bulk of the first oxide and/or the second oxide. In some such embodiments, the concentration of oxygen atoms in the conductive oxide interface is no more than 99% or no more than 98% or no more than 95% or no more than 90% or no more than 80% or no more than 50% or no more than 20% of concentration of oxygen atoms in the bulk of the first oxide.

According to some of any of the embodiments relating to a composite, the second oxide is in an amorphous form (e.g., amorphous Al₂O₃). In some such embodiments, the conductive oxide interface is characterized by a sheet resistance of no more than 10⁵ Ω/square (e.g., according to any of the respective embodiments described herein). In some embodiments, the conductive oxide interface is characterized by a sheet resistance of no more than 3·10⁴ Ω/square (e.g., according to any of the respective embodiments described herein). In some embodiments, the conductive oxide interface is characterized by a sheet resistance of no more than 10⁴ Ω/square (e.g., according to any of the respective embodiments described herein). In some embodiments, the conductive oxide interface is characterized by a sheet resistance of no more than 3·10³ Ω/square (e.g., according to any of the respective embodiments described herein). In some embodiments, the conductive oxide interface is characterized by a sheet resistance of no more than 10³ Ω/square (e.g., according to any of the respective embodiments described herein).

Without being bound by any particular theory, it is believed that a combination of amorphous second oxide and low conductive oxide interface (e.g., according to any of the respective embodiments described herein) allows for an advantageous combination of relatively low-cost and/or scalable preparation techniques with high performance, which has not been obtainable by prior methodologies.

According to some of any of the respective embodiments, upon subjecting the composite to a threshold voltage, the composite transitions from a state characterized by a low resistance to a state characterized by a high resistance (or vice versa). In some such embodiments, upon subjecting the composite to a second threshold voltage, the composite transitions from the state characterized by high resistance back to the state characterized by a low resistance (or vice versa), e.g., such that the transitioning between high resistance and low resistance states is reversible. The composite may optionally be capable of being subjected to at least 100 cycles, at least 1,000 cycles, at least 10,000 cycles, at least 100,000 cycles, or at least 1,000,000 cycles of reversible transitioning between the high resistance and low resistance states, e.g., cycles of application of the abovementioned threshold voltages.

In some of any of the embodiments relating to states characterized by a high resistance and a low resistance, the high resistance is at least 10-fold the low resistance. In some embodiments, the high resistance is at least 30-fold the low resistance. In some embodiments, the high resistance is at least 100-fold the low resistance. In some embodiments, the high resistance is at least 300-fold the low resistance. In some embodiments, the high resistance is at least 1000-fold the low resistance.

It is to be noted that the resistance of a composite described herein differs from a sheet resistance of a conductive oxide interface described herein. Whereas the sheet resistance relates to electrical conduction in the plane of the interface, resistance of a composite relates to electrical conduction outside the interface, e.g., through the bulk of the first oxide and/or second oxide (optionally in a direction perpendicular to the plane of the interface). In exemplary embodiments, the resistance of a composite relates to electrical conduction through the second oxide (e.g., between the conductive oxide interface and an electrode on the distal surface of the second oxide).

According to some of any of the embodiments relating to a composite, the composite is in a form of a device or a component of a device, for example, wherein the device further comprises an electric conductor in functional contact with at least one of the first oxide and second oxide.

A conductive oxide interface according to any of the respective embodiments described herein may optionally behave as a quantum well, that is, exhibit discrete allowable energy levels. Such a quantum well may optionally be included in any device in which a quantum well is useful, for example, a transistor, an optical sensor, and/or an electromagnetic radiation emitter (e.g., pulse laser or light-emitting diode (LED)).

As known in the art, such behavior is associated with quantum confinement caused by a low degree of thickness, comparable to a particle (e.g., electron) wavelength. In a conductive oxide interface according to any of the embodiments described herein, quantum well behavior may optionally be associated with the thinness of the conductive oxide interface (perpendicular to the plane of the interface), but also optionally associated with thinness in one or more dimension parallel to the interface, for example, when a layer of first oxide and/or layer of second oxide is thin in at least one dimension parallel to the interface.

Examples of devices which may optionally comprise a composite according to any of the embodiments described herein include, without limitation, a memory cell, a transistor, a chemical sensor, an optical sensor, an electromagnetic radiation emitter (optionally a laser or light-emitting diode), and a spin-logic device (e.g., wherein interaction between a magnetic field and spin, such as spin of electrons in a 2 DEG, is utilized for information processing).

Without being bound by any particular theory, it is believed that a composite comprising a conductive oxide interface (according to any of the respective embodiments described herein) may replace a semiconductor (e.g., doped or non-doped silicon) in a wide variety of devices.

Herein, the term “memory cell” encompasses any electronic circuit that stores a bit of binary information which can be controlled (e.g., “set” from 0 to 1, and/or “reset” from 1 to 0). The binary information may optionally be associated, e.g., with the presence of a high resistance state or low resistance state (e.g., according to any of the respective embodiments described herein).

A transistor (e.g., a field-effect transistor) may optionally utilize the conductive oxide interface as a channel between a source and drain (the source and drain optionally being separated by an oxide, e.g., the first oxide), and an oxide (e.g., the second oxide) as a gate oxide (e.g., in functional contact with a gate electrode). It is noted that in some transistors, the term “base” is used instead of “gate”, the term “emitter” is used instead of drain”, and the term “collector” is used instead of “source”, and such transistors are also encompassed as embodiments of the invention.

Alternatively or additionally, a transistor may optionally be a spin-based transistor.

Herein, the term “optical sensor” encompasses any device which emits a signal (e.g., electrical signal) upon exposure to light. The purpose of the sensor may optionally be to detect light, particularly light in a small region (e.g., as part of a digital camera); or to convert light energy to the signal, such as in production of electricity (e.g., as in a photovoltaic cell).

Potential applications for a conducting oxide interface (and/or 2 DEG) and structures suitable for such applications are further described, for example, in Hwang [Nature Materials 2012, 11:103], and Bogorin et al. [“LaAlO3/SrTiO3-Based Device Concepts” in Tsymbal, E. Y.; Dagotto, E.; Eom, C. B.; Ramesh, R. (eds.), Multifunctional Oxide Heterostructures. Oxford University Press, 24 Nov. 2010], which are each incorporated herein by reference.

According to an aspect of some embodiments of the invention, there is provided an article of manufacture (e.g., computer, mobile phone, memory card, USB drive, digital audio player, digital camera, synthesizer, video game, scientific instrument, robot, medical electronic device, photovoltaic cell, illumination, LED displays, fiber optic devices, and/or component thereof) comprising a device according to any of the embodiments described herein. In some such embodiments, the article of manufacture is an electronics product.

In some embodiments, there is provided a computer, mobile phone, digital audio player, synthesizer and/or video game which comprises one or more memory cell comprising a composite according to any of the respective embodiments described herein, one or more transistor comprising a composite according to any of the respective embodiments described herein, and/or one or more spin-logic device comprising a composite according to any of the respective embodiments described herein (each of which may optionally be integrated into an integrated circuit chip); and/or one or more light emitter comprising a composite comprising a composite according to any of the respective embodiments described herein (optionally integrated into a screen). Alternatively or additionally, the aforementioned article of manufacture comprises one or more transistor comprising a composite according to any of the respective embodiments described herein, integrated into a sound generation module (e.g., as part of an amplifier).

In some embodiments, there is provided a memory card and/or USB drive which comprises one or more memory cell comprising a composite according to any of the respective embodiments described herein, one or more transistor comprising a composite according to any of the respective embodiments described herein, and/or one or more spin-logic device comprising a composite according to any of the respective embodiments described herein (each of which may optionally be integrated into an integrated circuit chip).

In some embodiments, there is provided a digital camera which comprises one or more optic sensor comprising a composite according to any of the respective embodiments described herein (optionally integrated into an image acquisition module of the camera); and/or one or more memory cell comprising a composite according to any of the respective embodiments described herein, one or more transistor comprising a composite according to any of the respective embodiments described herein, and/or one or more spin-logic device comprising a composite according to any of the respective embodiments described herein (each of which may optionally be integrated into an information processing module and/or control module); and/or one or more light emitter comprising a composite according to any of the respective embodiments described herein (optionally integrated into an image display module).

In some embodiments, there is provided a robot, scientific instrument and/or medical electronic device which comprises one or more memory cell comprising a composite according to any of the respective embodiments described herein, one or more transistor comprising a composite according to any of the respective embodiments described herein, and/or one or more spin-logic device comprising a composite according to any of the respective embodiments described herein (each of which may optionally be integrated into an information processing module and/or control module); and/or one or more optic sensor and/or chemical sensor comprising a composite according to any of the respective embodiments described herein (optionally integrated into an information acquisition module).

An article of manufacture according to any of the respective embodiments described herein may optionally comprise, for example, a random access memory (RAM) device (e.g., comprising multiple memory cells according to any of the embodiments described herein), optionally a resistive RAM (ReRAM) device. The random access memory (RAM) device may optionally form a part of an integrated circuit chip.

Herein, the terms “random access memory” and “RAM” refer to a form of computer memory that can be read and changed (e.g., written) in any order, for example, to store working data and/or machine code. In contrast, in other types of computer memory, the time to read and write data items varies significantly depending on their physical locations on the recording medium (e.g., due to mechanical limitations such as disk rotation speeds and arm movement).

Herein, the term “resistive RAM” refers to RAM wherein memory works by changing resistance across a dielectric (e.g., across a composite described herein or a portion thereof).

Resistive RAM may optionally be non-volatile, that is, the memory can retain stored information even after power is removed. Spin-logic devices may also optionally provide non-volatile RAM. Thus, the advantages of RAM (e.g., as discussed hereinabove) and the advantages of non-volatility may advantageously be obtained in combination, which combination is not obtainable by many other computer memory technologies. For example, magnetic tape is non-volatile but cannot be randomly accessed, whereas conventional RAM technologies (dynamic RAM and static RAM) are volatile.

In addition, many articles of manufacture which generate and/or detect light will be apparent to the skilled person. Such articles of manufacture may optionally comprise one or more electromagnetic radiation emitter devices according to any of the respective embodiments described herein to generate light and/or one or more optical sensor devices according to any of the respective embodiments described herein to detect light.

It is expected that during the life of a patent maturing from this application many relevant uses of a conductive oxide interface will be developed and the scope of the terms “device”, “article of manufacture” and “quantum well” are intended to include such new technologies a priori.

As used herein the term “about” refers to ±10%.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non-limiting fashion.

Materials And Experimental Methods

Materials:

A (001)-oriented STO (SrTiO₃) crystal surface was obtained from CrysTec GmbH. The substrate was prepared with a TiO₂-terminated surface according to procedures such as described by Wysocki et al. [ACS Omega 2020, 5:5824].

TiO₂ was deposited on the surface of a glass substrate or SiO₂-coated silicon substrate by atomic layer deposition using TTIP (titanium tetraisopropoxide) as the Ti precursor and H₂O as the O precursor. In some samples, TiO₂ was deposited instead by atomic layer deposition using TDMAT (tetrakis(dimethylamino)titanium) as the precursor and Ar:O₂ (4:1) plasma as the O precursor.

Determination of sheet resistance and estimated sheet electron density:

The 4-point sheet resistance (R_{S}) of obtained samples was determined experimentally (in the van der Pauw geometry) at the conductive oxide interface. The corners of the wafers were manually scrubbed and metal contacts were deposited by e-beam evaporation.

Estimated sheet electron densities (n_{S}) were calculated based on the measured sheet resistance (R_{S}) and nominal bulk mobilities (μₑ˜4.4 cm²V⁻¹ s⁻¹) via the formula:

n_{S}=(R_{S}·q·μₑ)⁻¹

where q is the elementary charge and μₑ the electron mobility. The true mobility values are expected to be lower due to surface defects, so the estimated sheet electron densities herein are likely underestimates.

### Example 1

Formation of conductive Al₂O₃/SrTiO₃ (AO/STO) interface A (001)-oriented STO (SrTiO₃) crystal surface was prepared according to procedures described hereinabove, and then exposed to ammonia (NH₃) plasma, inside an atomic layer deposition (ALD) chamber. The plasma was produced using the ALD chamber's radio frequency source at a power of 300 W and ammonia flow of 50 standard cubic cm per minute.

Shortly thereafter, a layer (about 4 nm thick) of AO (Al₂O₃) was deposited on the surface of the various samples by ALD, with trimethyl aluminum (TMA) and water as precursors, according to procedures such as described by Cohen-Azarzar et al. [J Appl Phys 2018, 123:245307] and Miron et al. (“Recipe B”) [J Appl Phys 2019, 126:185301], using a Fiji® G2 ALD chamber (Ultratech/Cambridge Nanotech) and a substrate temperature of 300° C. The duration of the water pulse was 0.3 second, that of TMA was 0.1 second, and the purge pulses were 5 seconds.

Several samples were prepared by depositing an AO layer on an STO surface pre-treated for various time durations with ammonia plasma, according to the procedures described hereinabove, and the obtained AO layer covered the conductive STO surface and protected it from the ambient environment. Plasma treatment of the STO and deposition of AO were performed in the same run without additional processes or complications.

The sheet resistance and sheet electron density the various samples were determined according to procedures described hereinabove, in order to evaluate the effect of plasma exposure duration on sheet resistance and sheet electron density.

As shown in FIGS. 1A and 1B, the duration of ammonia plasma treatment was strongly correlated to a reduction in sheet resistance (FIG. 1A) and increase in estimated sheet electron density (FIG. 1B) at the AO/STO interface, with an exposure time of 2 minutes being associated with a reduction of 3 orders of magnitude in sheet resistance (and increase of 3 orders of magnitude in estimated sheet electron density) as compared to an exposure time of 0.5 minute.

As further shown in FIG. 1B, the estimated sheet electron density of the samples treated with ammonia plasma for 2 minutes was almost 10¹⁵ electrons per cm², which is comparable to some of the highest values reported for STO interfaces [Xu et al., Adv Mater Interfaces 2016, 3:1500432; Jin et al., APL Mater 2014, 2:116109].

These results indicate that the resistivity of such interfaces can be readily controlled based on plasma exposure time, and that a wide range of useful resistivity values can be obtained.

The AO/STO interfaces were further analyzed by high-resolution scanning transmission electron microscopy (HRSTEM) with atomic resolution of the interface, using a high-angle annular dark field (HAADF) mode.

As shown in FIG. 2, the AO/STO samples exhibited atomically abrupt interfaces, with a single crystalline structure of STO.

These results indicate that the obtained interfaces are suitable for use in electronic devices, in which atomically abrupt interfaces may be important.

### Example 2

### Formation of Conductive Al₂O₃/TiO₂ Interface

Glass surfaces were coated with a layer of TiO₂ which was about 14 nm thick. The TiO₂ surface was then exposed to ammonia (NH₃) plasma for 1-15 minutes, according to procedures such as described in Example 1, and then a followed by depositing a layer (about 10 nm thick) of AO (Al₂O₃) on the surface, according to procedures such as described in Example 1.

As shown in FIG. 3, the duration of ammonia plasma treatment was strongly correlated to a reduction in sheet resistance at the Al₂O₃/TiO₂ interface, with an exposure time of 15 minutes being associated with a reduction of more than 3 orders of magnitude in sheet resistance as compared to no exposure to NH₃ plasma.

These results indicate that plasma treatment as described herein can produce a two-dimensional electron gas (2 DEG) at a variety of oxide interfaces.

The effect of TiO₂ layer thickness was then assessed by repeating the above experiments with TiO₂ layers of about 14 nm and about 20 nm in thickness.

As shown in FIG. 4, TiO₂ layer thickness was negatively correlated with sheet resistance, both before and after plasma treatment; and the duration of the plasma treatment was correlated to a reduction in sheet resistance in all samples.

These results indicate that TiO₂ layer thickness is correlated to conductivity of the 2 DEG at the oxide interface. As thicker TiO₂ layers are likely to be more crystalline, these results suggest that TiO₂ crystallinity is correlated to conductivity of the 2 DEG at the oxide interface.

In order to further investigate the association between crystallinity and 2 DEG conductivity, additional samples with TiO₂ layers (about 14 nm) were prepared as described hereinabove, except that the deposited TiO₂ layers were subjected to thermal annealing at 300° C. for 105 minutes or at 500° C. for 40 minutes prior to ammonia plasma treatment (for 15 minutes).

As shown in FIG. 5, the sheet resistance of a 14 nm-thick TiO₂ 2 DEG was reduced by annealing in a temperature-dependent manner.

These results indicate that TiO₂ crystallinity is associated with lower sheet resistance of oxide interfaces upon plasma treatment, and that such TiO₂ crystallinity may be obtained by a variety of manners (e.g., thicker TiO₂ layers or by thermal annealing).

### Example 3

### Resistive Memory Device Comprising Conductive Oxide Interface as Bottom Electrode

A device suitable for resistive random access memory was prepared, as depicted in FIG. 6, by covering a Si/SiO₂ substrate 10 with a thin layer 20 of ammonia plasma-treated TiO₂ and a thin layer 30 of Al₂O₃ to form a conductive Al₂O₃/TiO₂ interface 25, according to procedures such as described in Example 2, to serve as a bottom electrode of the device. Top electrodes were formed by depositing platinum pads 40 through a shadow mask onto the surface of the Al₂O₃ layer 30, using e-beam evaporation.

The electrical behavior of the device was analyzed by current voltage (I-V) measurements using a Keithley 2450 source meter unit (SMU) instrument.

The structures were evaluated by multiple I-V switching cycles, each comprising a dual voltage sweep between 0 V and −4 V and between 0 V and 3 V.

As shown in FIG. 7, the I-V results exhibit robust and abrupt switching for both set and reset events.

In order to evaluate the DC endurance behavior of this sample, the resistances of the high resistance and low resistance states were plotted as a function of the cycle number.

As shown in FIG. 8, switching between the high resistance and low resistance states occurred in each of the 20 cycles.

These results indicate a considerable degree of endurance of the memory device. It is noted that using the slow DC sweeps as a gauge of endurance forces much harsher conditions than practical working conditions of a memristive device (i.e., pulses).

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

1. A process of preparing a conductive oxide interface, the process comprising contacting a surface of a first oxide with a plasma of a reducing gas to obtain a treated surface, and depositing a second oxide on said treated surface, thereby obtaining a conductive oxide interface between said first oxide and said second oxide.

2. The process of claim 1, wherein said depositing comprises atomic layer deposition.

3-5. (canceled)

6. The process of claim 1, wherein said reducing gas comprises nitrogen atoms.

7-9. (canceled)

10. The process of claim 1, wherein a sheet resistance of said conductive oxide interface is within a range of from 10² to 10⁷ Ω/square.

11. (canceled)

12. The process of claim 1, wherein a carrier density of said conductive oxide interface is within a range of from 10¹¹ to 10¹⁶ per cm².

13-15. (canceled)

16. The process of claim 1, further comprising subjecting said first oxide to a thermal treatment at a temperature of at least 200° C., prior to said contacting with said plasma of a reducing gas.

17-20. (canceled)

21. A composite comprising a first oxide and a second oxide, and an interface between said first oxide and said second oxide which comprises a conductive oxide interface obtainable according to the process of claim 1.

22. A composite comprising a first oxide and a second oxide, and an interface between said first oxide and said second oxide which comprises a conductive oxide interface, the conductive oxide interface comprising nitrogen atoms.

23. The composite of claim 22, wherein a concentration of nitrogen atoms in said conductive oxide interface is greater than a concentration of nitrogen atoms in the bulk of said first oxide and/or said second oxide.

24. The composite of claim 22, wherein a concentration of oxygen atoms in said conductive oxide interface is less than a concentration of oxygen atoms in the bulk of said first oxide and/or said second oxide.

25-26. (canceled)

27. The composite of claim 22, wherein said conductive oxide interface is characterized by a sheet resistance within a range of from 10² to 10⁷ Ω/square.

28. (canceled)

29. The composite of claim 22, wherein said conductive oxide interface is characterized by a carrier density within a range of from 10¹¹ to 10¹⁶ per cm².

30. (canceled)

31. The composite of claim 22, wherein said first oxide is selected from the group consisting of SrTiO₃, KTaO₃, and TiO₂.

32. (canceled)

33. The composite of claim 22, wherein said second oxide is selected from the group consisting of Al₂O₃, SiO₂, Si₃N₄, TiO₂, Ta₂O₅, LaAlO₃, YAlO₃ and Hf₁₋ₓZrₓO_{y}, wherein x is in a range of from 0 to 1 and y is in a range of from about 1.5 to about 2.

34. The composite of claim 33, wherein said second oxide is Al₂O₃.

35. A composite comprising a first oxide and a second oxide, said second oxide being in an amorphous form, and an interface between said first oxide and said second oxide which comprises a conductive oxide interface characterized by a sheet resistance of no more than 10⁵ Ω/square.

36. (canceled)

37. The composite of claim 35, wherein said second oxide is selected from the group consisting of Al₂O₃, SiO₂, Si₃N₄, TiO₂, Ta₂O₅, LaAlO₃, YAlO₃ and Hf₁₋ₓZrₓO_{y}, wherein x is in a range of from 0 to 1 and y is in a range of from about 1.5 to about 2.

38. (canceled)

39. The composite of claim 35, wherein said conductive oxide interface comprises nitrogen atoms, a concentration of said nitrogen atoms in said conductive oxide interface is greater than a concentration of nitrogen atoms in the bulk of said first oxide and/or said second oxide.

40. (canceled)

41. The composite of claim 35, wherein a concentration of oxygen atoms in said conductive oxide interface is less than a concentration of oxygen atoms in the bulk of said first oxide and/or said second oxide.

42. The composite of claim 35, wherein said conductive oxide interface is characterized by a carrier density of at least 10¹⁴ per cm².

43-50. (canceled)
